(19) United States
(12) Patent Application Publication
(10) Pub. No.: US 2004/0040664 A1
(43) Pub. Date: Mar. 4, 2004

(54) Cathode pedestal for a plasma etch reactor

(76) Inventors: Jang Gyoo Yang, Sunnyvale, CA (US); Daniel J. Hoffman, Saratoga, CA (US); Brian C. Lue, Mountain View, CA (US); Tetsuya Ishikawa, Saratoga, CA (US); Douglas A. Buchberger JR., Livermore, CA (US); Semyon L. Kats, San Francisco, CA (US); Hamid Tavassoli, Santa Clara, CA (US); Kang-Lie Chiang, San Jose, CA (US); Heeyeop Chae, San Jose, CA (US)

Correspondence Address: Patent Counsel, APPLIED MATERIALS, INC., P.O. Box 450A, Santa Clara, CA, 95052, US

(21) Appl. No.: 10/452,819

(22) Filed: Jun. 2, 2003

Related U.S. Application Data
(60) Provisional application No. 60/385,753, filed on Jun. 3, 2002.
(60) Provisional application No. 60/434,959, filed on Dec. 19, 2002.

(51) Int. Cl. H01L 21/306

(52) U.S. Cl. 156/345.51

(57) ABSTRACT

Various embodiments of the present invention are generally directed to a plasma etch reactor. In one embodiment, the reactor includes a chamber, a pedestal disposed within the chamber, a gas distribution plate disposed within the chamber overlying the pedestal, a ring surrounding the pedestal, and an upper electrically conductive mesh layer and a lower electrically conductive mesh layer disposed within the pedestal. The ring has a raised portion. The upper electrically conductive mesh layer is disposed substantially above the lower electrically conductive mesh layer and is substantially the same size as a substrate configured to be disposed on the pedestal. The lower electrically conductive mesh layer is substantially annular in shape and is disposed around the periphery of the upper electrically conductive mesh layer and below the raised portion of the ring.

### CROSS-REFERENCE TO RELATED APPLICATIONS

This application claims benefit of U.S. provisional patent application serial No. 60/385,753, filed Jun. 3, 2002, and U.S. provisional patent application serial No. 60/434,959, filed Dec. 19, 2002, both of which are incorporated herein by reference.

### BACKGROUND OF THE INVENTION

1. Field of the Invention

Embodiments of the present invention generally relate to semiconductor substrate processing equipment and, more particularly, to a pedestal typically used inside a plasma etch reactor.

2. Description of the Related Art

Generally, a plasma etch reactor is used to process semiconductor wafers to produce microelectronic circuits. The reactor forms a plasma within a chamber containing the wafer to be processed. The plasma is formed and maintained by application of very high frequency (VHF) plasma source power coupled either inductively or capacitively into the chamber. For capacitive coupling of VHF source power into the chamber, an overhead electrode (facing the wafer) is powered by a VHF source power generator.

Recently, capacitively coupled plasma etch reactors have been used for dielectric etch applications at low pressures in nearly pure reactive ion etching (RIE) conditions, which required increased voltage capability (e.g., from about 4000 volts peak to peak to about 6000 volts peak to peak), creation of significant plasma at low pressures (e.g., about 30 mT), and increased efficiency of the chuck to allow the plasma to form at low pressures. Operating capacitively coupled plasma etch reactors under these conditions, however, often leads to a high voltage breakdown, high damage to the chuck, and poor etch rates, all of which may be caused by the lack of plasma density over the substrate surface. Recent investigations have discovered that the lack of plasma density was caused by a lossy transmission line that connects to the substrate.

Therefore, a need exists for an improved capacitively coupled plasma etch reactor that overcomes the deficiencies described above.

### SUMMARY

Various embodiments of the present invention are generally directed to a plasma etch reactor. In one embodiment, the reactor includes a chamber, a pedestal disposed within the chamber, a gas distribution plate disposed within the chamber overlying the pedestal, a ring surrounding the pedestal, and an upper electrically conductive mesh layer and a lower electrically conductive mesh layer disposed within the pedestal. The ring defines a raised portion. The upper electrically conductive mesh layer is disposed substantially above the lower electrically conductive mesh layer and is substantially the same size as a substrate configured to be disposed on the pedestal. The lower electrically conductive mesh layer is substantially annular in shape and is disposed around the periphery of the upper electrically conductive mesh layer and below the raised portion of the ring.

In another embodiment, the reactor further includes an insulation layer disposed on the pedestal and a plurality of gas flow openings disposed through the insulation layer. At least one gas flow opening includes a porous plug disposed therein. The porous plug is configured to provide an indirect pathway for gases to flow toward an upper surface of the insulation layer.

In yet another embodiment, the reactor further includes at least one lift pin opening disposed through the pedestal. The at least one lift pin opening includes a lift pin disposed therein configured to lift a portion of a substrate off an upper surface of the pedestal. The at least one lift pin opening has a pressure that is substantially less than a pressure inside the chamber during a process.

In still another embodiment, the reactor further includes a heat exchanger disposed inside the pedestal. The heat exchanger includes a plurality of channels. Each channel defines a plurality of protrusions disposed therein. The protrusions are configured to cause turbulence to a heat exchanger fluid contained inside the channels.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a plasma etch reactor chamber that includes various embodiments of the invention.

FIG. 2 illustrates in greater detail the structure of the cathode pedestal in accordance with an embodiment of the invention.

FIG. 3 illustrates in greater detail the configuration of the electrically conductive mesh layers in accordance with an embodiment of the invention.

FIG. 4 illustrates a schematic illustration of a bias tuning circuit in accordance with an embodiment of the invention.

FIG. 5 illustrates a dielectric sleeve surrounding the conductor in accordance with an embodiment of the invention.

FIG. 6 illustrates a cut-away side view of the dielectric sleeve in accordance with an embodiment of the invention.

FIG. 7A is a side view illustrating a version of the dielectric sleeve that is mechanically adjustable.

FIG. 7B is a side view illustrating a version having multiple sleeve sections that are each mechanically adjustable.

FIG. 8 illustrates a cross section view of a heat exchanger in accordance with an embodiment of the invention.

FIG. 9 illustrates a schematic bottom view of the heat exchanger of FIG. 8.

FIG. 10A illustrates a schematic top view of a channel of a heat exchanger with chevron protrusions in accordance with one embodiment of the invention.

FIG. 10B illustrates a schematic side view of a channel of a heat exchanger with bump protrusions in accordance with one embodiment of the invention.

### DETAILED DESCRIPTION

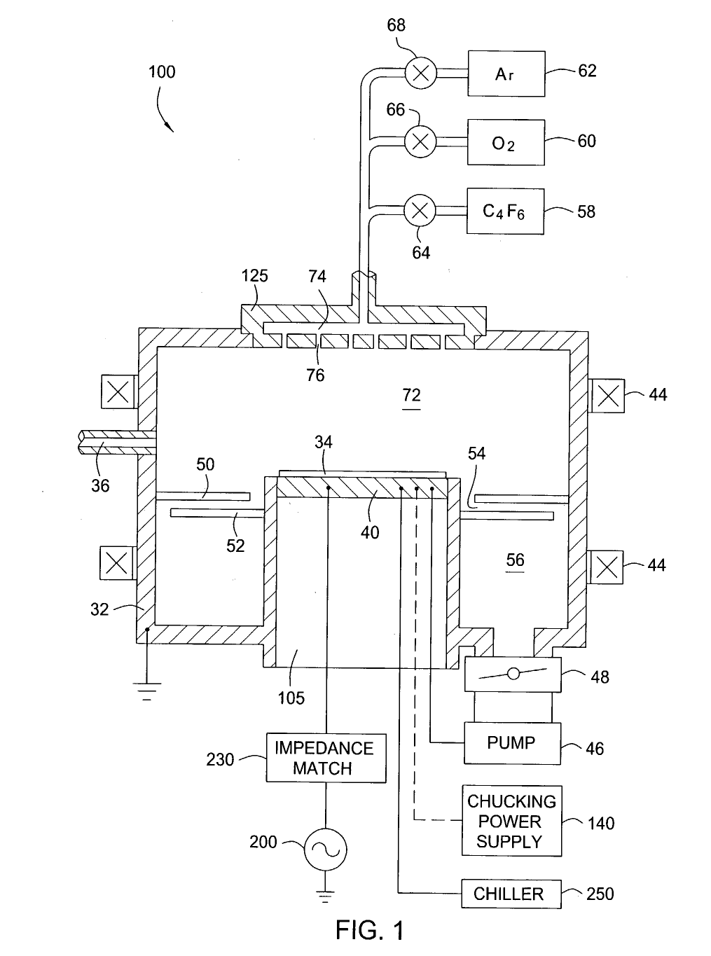

FIG. 1 illustrates an example of a capacitively coupled etch reactor 100 that includes various embodiments of the invention. This illustration is based on the MxP, eMax or Super-e etch reactors available from Applied Materials. It includes a grounded vacuum chamber 32, perhaps including liners to protect the walls. A substrate 110 is inserted into the chamber 32 through a slit valve opening 36 and placed on a cathode pedestal 105 with an electrostatic chuck 40 selectively clamping the wafer. The chuck may be powered with one or more power supplies. Fluid cooling channels may be positioned through the pedestal 105 to maintain the pedestal at reduced temperatures. A thermal transfer gas, such as helium, is supplied to openings in the upper surface of the pedestal 105. The thermal transfer gas increases the efficiency of thermal coupling between the pedestal 105 and the wafer 34, which is held against the pedestal 105 by the electrostatic chuck 40 or an alternatively used peripheral wafer clamp.

An RF power supply 200, generally operating at 13.56 MHz, is connected to the cathode pedestal 105 and provides power for generating the plasma while also controlling the DC self-bias. Magnetic coils 44 powered by one or more current supplies surround the chamber 32 and generate a slowly rotating (on the order of seconds and typically less than 10 ms), horizontal, essentially DC magnetic field in order to increase the density of the plasma. A vacuum pump system 46 pumps the chamber 32 through an adjustable throttle valve 48. Shields 50, 52 not only protect the chamber 32 and pedestal 105 but also define a baffle 54 and a pumping channel 54 connected to the throttle valve 48.

Processing gases are supplied from gas sources 58, 60, 62 through respective mass flow controllers 64, 66, 68 to a gas distribution plate 125 positioned in the roof of the chamber 32 overlying the wafer 34 and separated from it across a processing region 72. The distribution plate 125 includes a manifold 74 configured to receive the processing gases and communicate with the processing region 72 through a showerhead having a large number of distributed apertures 76 so that a more uniform flow of processing gas may be injected into the processing region 72.

Other details of the reactor 100 are further described in commonly assigned U.S. Pat. No. 6,451,703, entitled “Magnetically Enhanced Plasma Etch Process Using A Heavy Fluorocarbon Etching Gas”, issued to Liu et al. and U.S. Pat. No. 6,403,491, entitled “Etch Method Using A Dielectric Etch Chamber With Expanded Process Window”, issued to Liu et al., which are both incorporated by reference herein to the extent not inconsistent with the invention. Although various embodiments of the invention will be described with reference to the above-described reactor, the embodiments of the invention may also be used in other reactors, such as one described in commonly assigned U.S. Ser. No. 10/028,922 filed Dec. 19, 2001, entitled “Plasma Reactor With Overhead RF Electrode Tuned To The Plasma With Arcing Suppression”, by Hoffman et al., which is incorporated by reference herein to the extent not inconsistent with the invention, and is commercially available as the Enabler® Reactor from Applied Materials, Inc. of Santa Clara, Calif.

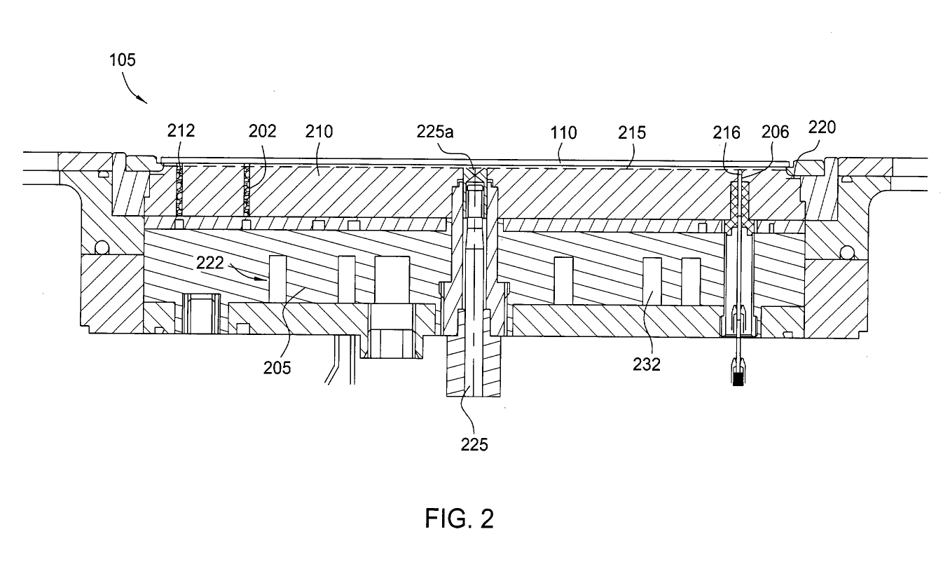

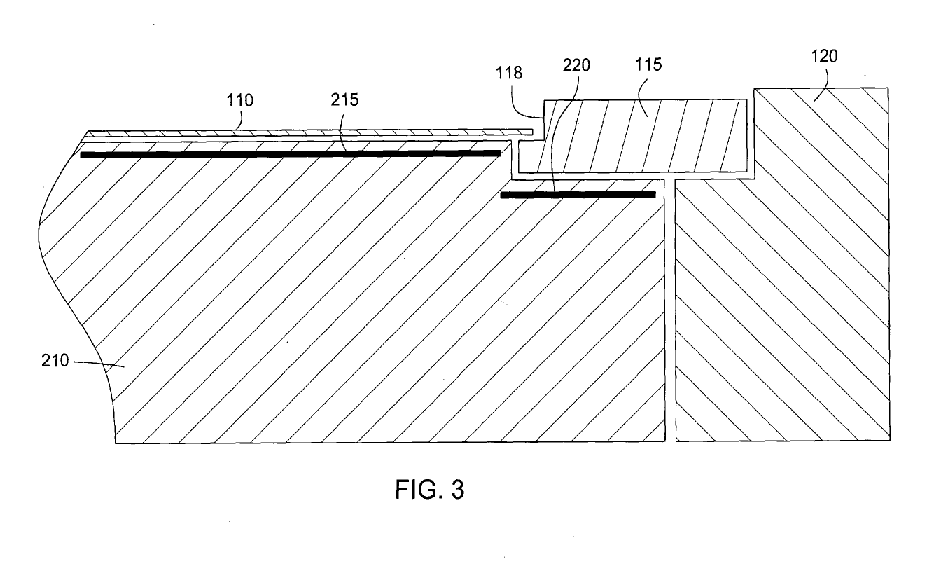

Dual Mesh. FIG. 2 illustrates in greater detail the structure of the cathode pedestal 105. The cathode pedestal 105 includes a metal pedestal layer 205 and an insulation layer 210, which may be referred to as a puck. The insulation layer 210 includes an upper electrically conductive mesh layer 215 and a lower electrically conductive mesh layer 220. The substrate 110 is generally disposed on top of the insulation layer 210. The specific orientation of the mesh layers will be described below with reference to FIG. 3. The electrically conductive mesh layers 215, 220 and the metal pedestal layer 205 may be made from molybdenum and aluminum respectively. The insulation layer 210 may be made from a dielectric material, such as aluminum nitride or alumina, for example. The electrically conductive mesh layers 215, 220 are configured to supply the RF bias voltage to control ion bombardment energy at the surface of the substrate 110. The electrically conductive mesh layers 215, 220 may also be used for electrostatically chucking and de-chucking the substrate 110. In such a case, the electrically conductive mesh layers may be connected to a chucking power supply 140. An example of such a power supply is disclosed in commonly assigned U.S. Pat. No. 6,005,376, issued Dec. 21, 1999, which is incorporated herein by reference. The electrically conductive mesh layers 215, 220 may not necessarily be grounded and consequently may have a floating electric potential or a fixed D.C. potential in accordance with conventional chucking and de-chucking operations.

FIG. 2 further illustrates an RF conductor 225 extending through the cathode pedestal 105. The RF conductor 225 is electrically coupled to an RF bias generator 200 through an RF bias impedance match element 230 (shown in FIG. 1). The RF bias generator 200 is configured to apply power to the substrate 110 through the RF bias impedance match element 230 and the RF conductor 225 in a high frequency (HF) band, such as from about 2 MHz to about 13.56 MHz. The RF conductor 225 is generally insulated from grounded conductors such as the metal pedestal layer 205. The RF conductor 225 has a top termination or bias power feed point 225a in electrical contact with the upper electrically conductive mesh 215.

FIG. 3 illustrates in greater detail the configuration of the electrically conductive mesh layers 215, 220 in accordance with an embodiment of the invention. The upper electrically conductive mesh layer 215 is generally shaped like a disk and has substantially the same size as the substrate 110. The mesh layer 215 is disposed below the substrate 110 and substantially parallel to the substrate 110. The lower electrically conductive mesh layer 220 is substantially annular in shape, disposed generally below the upper electrically conductive mesh layer 215 and parallel to the upper electrically mesh layer 215, and substantially proximate the periphery of the cathode pedestal 105. The lower electrically conductive mesh layer 220 is electrically coupled to the RF conductor 225 through an electrically conductive line that runs along a diameter of the lower electrically conductive mesh layer 220. In this manner, the lower electrically conductive mesh layer 220 is configured to supply RF power to periphery portion of the substrate 110. Other details of the upper and lower electrically conductive mesh layers 215, 220 may be described in commonly assigned U.S. Pat. No. 6,232,236 entitled “Apparatus and Method for Controlling Plasma Uniformity in a Semiconductor Wafer Processing System”, issued to Shan et al., which is incorporated by reference herein to the extent not inconsistent with the invention.

FIG. 3 further illustrates a semiconductor ring 115 in accordance with an embodiment of the invention. The semiconductor ring 115 may also be referred to as a process kit. The lower electrically conductive mesh layer 220 is disposed below the semiconductor ring 115. The semiconductor ring 115 defines a raised portion 118. The lower electrically conductive mesh layer 220 in combination with the upper portion 118 are configured to shape the electric field at or near the periphery of the substrate 110. More specifically, the combination is used to reduce the high concentration of non perpendicular field lines that are typically disposed at or near the periphery portion of the substrate 110, causing an edge tilting effect, which causes vias to be etched in a sideway manner. By disposing the lower electrically conductive mesh layer 220 below the semiconductor ring 115 and defining the raised portion 118, the electric field lines at or near the periphery of the substrate 110 are disposed substantially perpendicular to the substrate 110, and thereby eliminating the edge tilting effect. In one embodiment, the raised portion 118 is about 1.5 mm to about 3 mm in height.

Bias Tuning Circuit. In some chambers, such as the one described in commonly assigned U.S. Ser. No. 10/028,922 filed Dec. 19, 2001, entitled “Plasma Reactor With Overhead RF Electrode Tuned To The Plasma With Arcing Suppression”, by Hoffman et al., VHF power may be applied to the gas distribution plate 125, thereby making the gas distribution plate an electrode. The power that is applied to the gas distribution plate is commonly referred to as the “source” power as opposed to the “bias” power that is applied to the pedestal. In one embodiment, the VHF power is applied at high frequency, such as 100-200 MHz. In other embodiments, the source power frequency may be lower, e.g., 13.56 MHz or 12.56 MHz.

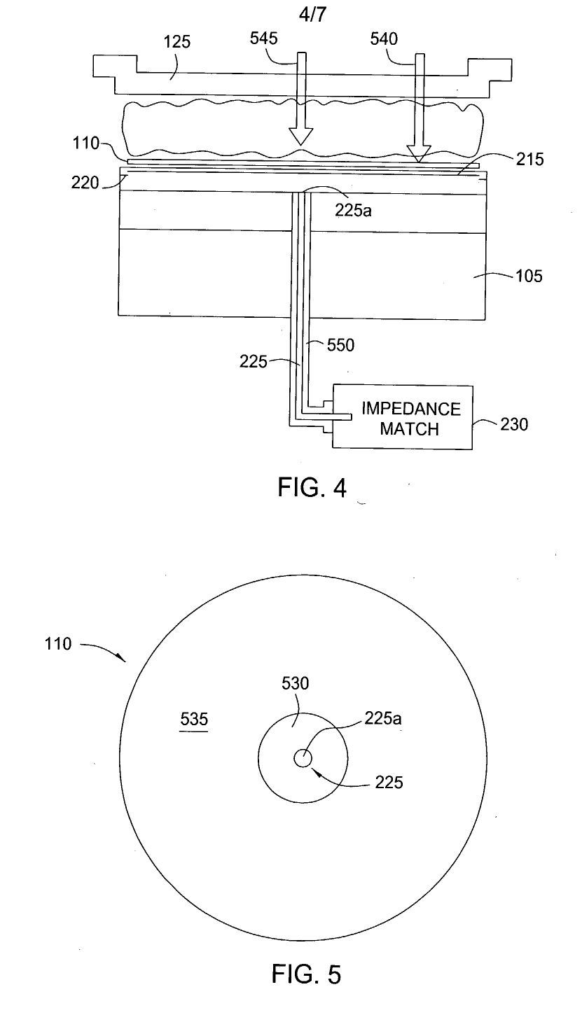

FIG. 4 is a schematic illustration of a circuit, which includes the overhead electrode 125, the RF bias applied through the cathode pedestal 105 and the elements of the cathode pedestal 105. FIG. 5 illustrates a top plan view of the substrate 110, the termination or feed point 225a, and the RF conductor 225. The RF return path provided by the cathode pedestal 105 consists of two portions in the plane of the substrate 110, namely a radially inner portion 530 centered about and extending outwardly from the feed point 225a and the radially outer annular portion 535. The RF return paths provided by the two portions 530, 535 are different, and therefore the two portions 530, 535 present different impedances to the VHF power radiated by the overhead electrode 125.

The primary RF return path 545 is provided by the conductive mesh layers 215, 220, which are coupled through the cathode pedestal 105 and the RF conductor 225. The RF return path 540 passing through the outer annular portion 535 is dominated by reactive coupling through the substrate 110 and across the conductive mesh layers 215, 220 to the cathode pedestal 105. In contrast, the RF return path 545 through the inner portion 530 is dominated by the reactive impedance of the feed point 225a. As a result, the two RF return paths often cause non-uniform coupling to RF power if the impedance is not uniform across the substrate 110.

Since the two RF return paths are physically different, they tend to offer different impedances to the VHF power radiated by the overhead electrode 125. Such differences may cause non-uniformities in radial distribution across the substrate surface of impedance to the VHF power, rendering source power coupling to the plasma nonuniform and giving rise to nonuniform radial distribution of plasma ion density near the surface of the substrate 110. This in turn can cause processing non-uniformities that unduly narrow the process window. Accordingly, the reactor 100 may include certain features that adjust the feed point impedance presented by the RF conductor 225 to the VHF power, thereby enabling a more uniform radial distribution of impedance across the substrate surface and a more uniform coupling of VHF power across the substrate surface.

A principal purpose of this adjustment in the feed point impedance is to bring the impedance at the feed point 225a to at least nearly zero at the source power frequency (i.e., the VHF frequency of the overhead electrode 125 from about 100 MHz to about 200 MHz). As a result of this adjustment, the RF current return path is dominated by the conductive mesh layers 215, 220 through the RF conductor 225 while minimizing the current through the cathode pedestal 105. Consequently, the impedances of the regions 530 and 535 can be made to be at least substantially the same.

In order to adjust the feed point impedance, a dielectric cylindrical sleeve 550 surrounds the RF conductor 225. The axial length and the dielectric constant of the material constituting the sleeve 550 determine the feed point impedance presented by the RF conductor 225 to the VHF power. In one example, the length and dielectric constant of the sleeve 550 is selected to bring the feed point impedance to nearly zero at the VHF source power frequency (e.g., about 100-200 MHz). In a working example, the feed point impedance without the sleeve 550 was (0.9+j41.8) ohms and with the sleeve 550 was nearly a short circuit at (0.8+j0.3) ohms. The impedance presented by the outer region 535 surrounding the feed point 225a is nearly a short at the corresponding frequency (due mainly to the presence of the conductive mesh layers 215, 220). Therefore, in the latter example the sleeve 550 may bring the feed point impedance at the source power frequency to a value closer to that of the surrounding region. Here, the impedance of the region surrounding the feed point is determined mainly by the conductive mesh layers 215, 220.

The sleeve 550 may also include features facilitating the foregoing improvement in VHF power distribution while simultaneously solving a separate problem, namely improving the uniformity in the electric field created by the RF bias power (at 13.56 MHz for example) applied to the substrate 110 by the RF conductor 225. The problem is how to adjust radial distribution of VHF power coupling for maximum uniformity of plasma ion density while simultaneously adjusting the HF bias power electric field distribution across the wafer surface for maximum uniformity. Maximum uniformity would be attained if the feed point impedance at the HF bias power frequency were brought nearer to that of the surrounding region 535 dominated by the conductive mesh layers 215, 220 (without altering the feed point impedance at the VHF source power frequency). This problem is solved by dividing the sleeve 550 along its cylindrical axis into plural cylindrical sections, and adjusting or selecting the length and dielectric constant of each section independently. This provides several independent variables that may be exploited to permit matching the feed point impedance to that of the surrounding region at both the bias frequency (e.g., about 13.56 MHz) and at the source frequency (e.g., about 100-200 MHz) simultaneously.

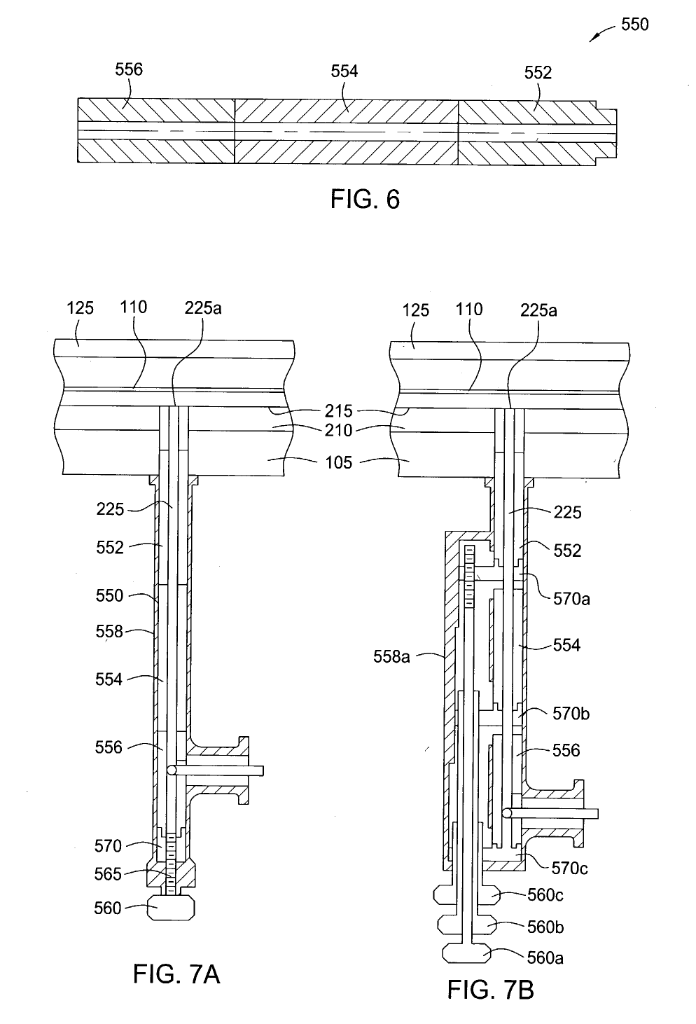

FIG. 6 illustrates sleeve 550 divided into three sections, namely a top section 552, a middle section 554 and a bottom section 556, in accordance with an embodiment of the invention. The top section 552 may be made from polytetraflouroethylene and about three inches in length, the middle section 554 may be made from alumina and about four inches in length, and the bottom section 556 may be made from polytetraflouroethylene and about three inches in length. The length and dielectric constant of the sleeve top section 552 may be selected and fixed to optimize the HF bias power distribution exclusively. The lengths and dielectric constants of the remaining sleeve sections 554, 556 may then be selected to optimize VHF source power distribution by the overhead electrode while leaving the HF bias power distribution optimized.

FIG. 7A illustrates how the sleeve 550 may be assembled to be adjustable during use. An external control knob 560 is provided on the reactor to turn a screw 565 threadably engaged with a sleeve support 570 coupled to the bottom of the sleeve 550. As the knob 560 is rotated, the sleeve support 570 travels axially along the axis of the threaded screw 565, forcing the entire sleeve 550 to travel in the same direction (either up or down) within a sleeve guide 558. The knob 560 permits the user to adjust the feed point impedance by moving the sleeve 550 up or down along the RF conductor 225 during (or shortly before) operation of the reactor. The sleeve support 570 may move the entire sleeve 550 (for example, all three sections 552, 554, 556 as a unit together). Or, the sleeve support 570 may be coupled to only one or two of the three sections 552, 554, 556 so that only one or two of the three sections is moved by rotating the knob 560. FIG. 7B illustrates that three knobs 560a, 560b, 560c may separately engage three sleeves supports 570a, 570b, 570c. The three sleeve supports 570a, 570b, 570c are individually connected to respective ones of the three sleeve sections 552, 554, 556 so that the positions of each of the sleeve sections 552, 554, 556 are separately determined within the sleeve guide 558a by the three knobs 560a, 560b, 560c. Other details of the bias tuning circuit as described with reference to FIGS. 4-7B are described in commonly assigned U.S. Ser. No. 10/235,988, filed Sep. 4, 2002 and entitled “Capacitively Coupled Plasma Reactor With Uniform Radial Distribution of Plasma”, by Yang et al., which,is incorporated by reference herein to the extent not inconsistent with the invention.

Porous Plugs. Referring back to FIG. 2, the cathode pedestal 105 in accordance with an embodiment of the invention is illustrated. The cathode pedestal 105 includes a plurality of gas flow openings 202 disposed through the insulation layer 210 at or around the periphery of the cathode pedestal 105. Each opening includes a porous plug 212. The openings 202 combined with the porous plugs 212 contained therein are configured to permit gas (such as, helium or argon) flow from cooling gas sources (not shown) to the upper surface of the cathode pedestal 105. The porous plugs 212 may be made from a dielectric, such as alumina having a porosity ranging from about 10% in volume to about 60% in volume, with interconnected openings that form continuous passageways through the dielectric material. The porous plugs 212 may also be made from a material selected from a group consisting of ceramic compositions, engineering thermoplastics, thermosetting resins, filled engineering thermoplastics, filled thermosetting resins, and combinations thereof. When the porous plugs 212 are formed using traditional molding and sintering methods, the particles used in the molding or sintering are of the same order of magnitude in size as the porosity and are bonded in a substantially random orientation,,producing passageways that avoid the straight line of sight configuration. In this manner, arcing or glow discharge occurring within the openings 202 may be minimized and uniform electric field from the grounded pedestal to the plasma may be generated. Other details of the porous plugs are described in commonly assigned U.S. Pat. No. 5,720,818, entitled “Conduits For Flow Of Heat Transfer Fluid To The Surface Of An Electrostatic Chuck”, issued to Donde et al., which is incorporated by reference herein to the extent not inconsistent with the invention.

Pumped Lift Pins. FIG. 2 further illustrates one of a plurality of lift pin openings 206 having a lift pin 216 in each opening 206. The lift pin openings 206 are disposed through the cathode pedestal 105 to allow the lift pins 216 to pass therethrough to lift the substrate 110 off the upper surface of the cathode pedestal 105 once the power has been turned off and the clamping force terminated. During operation of the chamber, the pressure in the gas flow openings 202 generally ranges from about 5 to about 40 T, while the chamber operating pressure ranges from about 10 to about 500 mT. Some of the cooling gases flowing through the gas flow openings 202 often leak into the lift pins openings 206, which may cause arcing (which may be referred to as back side arcing) during operation of the chamber. In accordance with an embodiment of the invention, the lift pin openings 206 are configured to be pumped with vacuum. In this manner, the pressure inside the lift pin openings 206 may be reduced, thereby reducing the likelihood for arcing to occur within the lift pin openings 206. The lift pin openings 206 may be pumped with vacuum such that the pressure inside the openings 206 is less than the chamber operating pressure. The lift pin openings 206 may be pumped by either the chamber vacuum pump 46, or a separate pump. As such, backside cooling gas is constantly evacuated from the openings 206 and does not accumulate at a pressure that facilitates arcing during chamber operation.

Optimization of Insulation Layer. It has recently been observed that operating the chamber at low pressures (e.g., from about 0.1 mT to about 50 mT) generally leads to minimal or no plasma ion density near the surface of the substrate 110. A determination was made that the lack of plasma ion density near the surface of the substrate 110 is caused by a high power loss from the RF bias generator 200 to the substrate 110. More specifically, most of the power loss occurs in the insulation layer 210. Thus, it can be deduced that the lack of plasma ion density near the surface of the substrate 110 is caused by lack of power to the substrate 110. One solution to minimize power loss in the insulation layer 210 is to increase the thickness of the insulation layer 210. In one embodiment, the thickness of the insulation layer 210 is increased by about two fold, e.g., about 25-30 mm thick. By increasing the thickness of the insulation layer 210 to about 25-30 mm, the plasma conductance inside the chamber falls into a range from about 0.001+j0.01 to about 0.004+j0.02. Further, by increasing the thickness of the insulation layer 210 by about two fold, the shunt capacitance (stray resonance) coupling to ground is reduced by about 50% and the power loss that occurs in the insulation layer 210 is minimized, thereby increasing the amount of power applied to the substrate 110. As the amount of power transferred from the RF bias generator 200 to the substrate 110 increases, the voltage capability and power capability of the RF bias generator 200 also increases. An increased power capability in turn leads to an increase in etch rate. For example, for a 300 mm substrate, the voltage capability at low pressures (e.g., from about 10-50 mT) may be increased to about 7500 volts peak to peak and the power capability may be increased to about 6000 watts.

Heat Exchanger. FIG. 2 further illustrates a heat exchanger 222 in accordance with an embodiment of the invention. The heat exchanger 222 is configured to provide a uniform temperature distribution across the cathode pedestal 105. In one embodiment, the heat exchanger 222 is defined within the metal pedestal layer 205. The heat exchanger 222 may also be defined within the insulation layer 210. The heat exchanger 222 defines a plurality of channels 232 configured to circulate heat transfer fluid to remove heat from the cathode pedestal 105. The heat exchanger 222 is connected to a chiller equipment 250 that supplies the heat transfer fluid to the heat exchanger. The chiller equipment may include a pump to circulate the heat exchanger fluid through the channels 232. As the heat transfer fluid is circulated through the channels 232, the heat from the cathode pedestal 105 is absorbed by the heat transfer fluid. After circulating the heat transfer fluid through the channels 232, the heated heat transfer fluid is returned to the chiller equipment for further processing or recirculation.

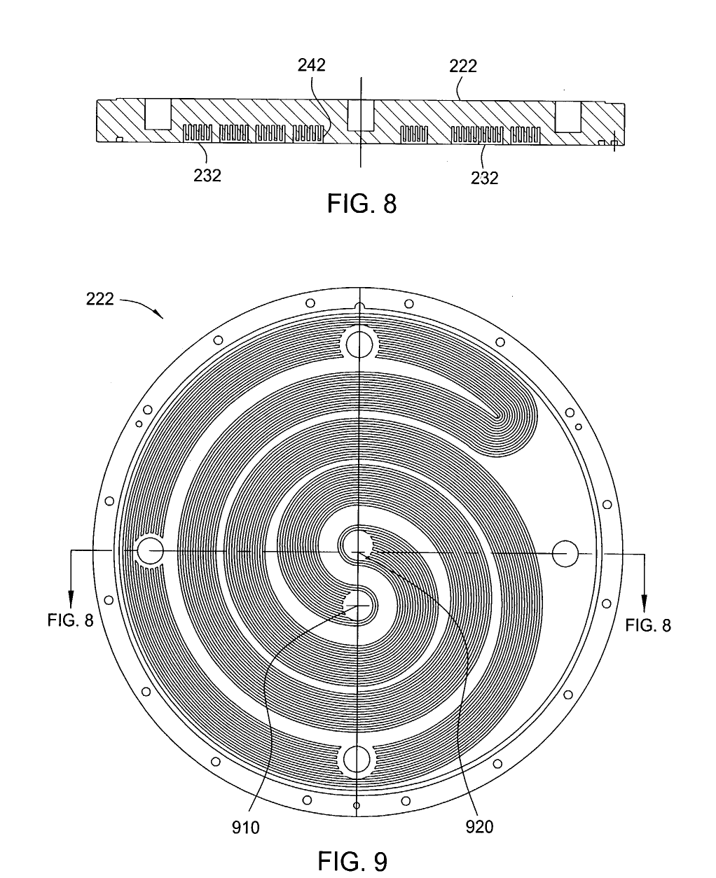

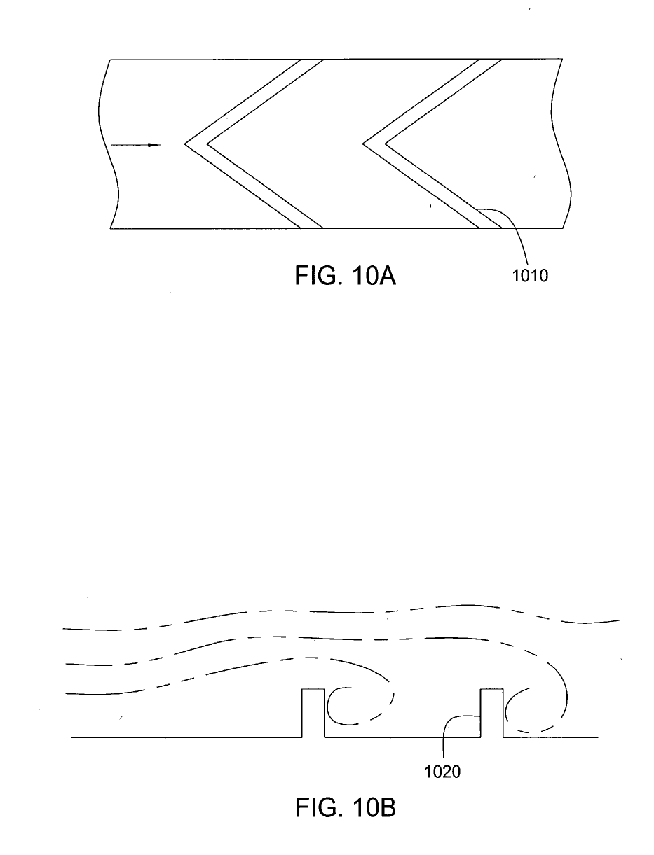

FIG. 8 illustrates a cross section view of a heat exchanger 222 in accordance with an embodiment of the invention. The heat exchanger 222 defines channels 232 that have protrusions disposed along the wetted surfaces of the channels 232. The protrusions are configured to bring about turbulence to the heat exchanger fluid. The turbulence in the heat exchanger fluid causes more of the heat exchanger fluid to contact the hot walls of the heat exchanger 222, which in turn result in a more efficient heat exchanger. The protrusions may also be configured to increase the surface area of the wetted area in contact with the metal pedestal layer 205. In this manner, the protrusions may be used to locally adjust the thermal resistance between the substrate 110 and the heat exchanger 222. The protrusions may be in the form of fins, bumps, chevrons, spines, or helical structures. As illustrated in FIG. 8, the channels 232 define a plurality of fins 242 on the inside portion (i.e., the wetted area) of the channels 232. For example, in a metal pedestal layer that is about 2 inch thick, each fin 242 may be about 1/16 inch wide and about ⅜ inch high. The taller the fins, the more wetted area is in contact with the metal pedestal layer 205, from which heat is transferred. The fins 242 generally have more wetted area in contact with the metal pedestal layer 205 than other type of protrusions. Consequently, the fins 242 are configured to remove more heat from the metal pedestal layer 205 than other type of protrusions, since the amount of heat removed is directly proportional to the amount of wetted area in contact with the metal pedestal layer 205. Generally, the fins 242 are used as protrusions in thicker metal pedestal layers, such as about 1.5 inch or greater. Other forms of protrusions, such as chevrons 1010 (shown in FIG. 10A) and bumps 1020 (shown in FIG. 10B), are generally used in thinner metal pedestal layers, such as less than about 1 inch. If the chevrons 1010 are used as the protrusions, the pointed portions of the chevrons 1010 are disposed in an upstream direction to project the most turbulence. The height of each chevron may be about 10% to about 15% of the depth of the channel 232.

FIG. 9 illustrates a schematic bottom view of the heat exchanger 222 of FIG. 8. The heat exchanger 222 includes an input conduit 910 and an output conduit 920 connected to the input conduit 910. The heat exchanger fluid is received at the input conduit 910 and is transferred to the chiller equipment through the output conduit 920. Consequently, the heat exchanger fluid contained in the input conduit 910 is generally cooler than the heat exchanger fluid contained in the output conduit 920. In one embodiment, the position of the input conduit and the position of the output conduit are reversed. The channels 232 are configured such that the input conduit 910 is positioned substantially adjacent the output conduit 920. In this manner, the thermal resistance between the input conduit 910 and the output conduit 920 remains substantially constant, thereby keeping temperature non-uniformity between the input conduit 910 and the output conduit 920 to a minimal. In one embodiment, the input conduit 910 is connected to the output conduit 920 at a location at which the temperature of the heat exchanger fluid in the input conduit 910 is about the same as the temperature of the heat exchanger fluid in the output conduit 920. The input conduit 910 and the output conduit 920 may be configured in a spiral formation in order to minimize the number of sharp turns and to increase the number of loops formed by the input conduit 910 and the output conduit 920. Furthermore, the input conduit 910 and the output conduit may be configured such that the heat exchanger fluid inside the input conduit 910 and the output conduit 920 travel in opposite directions and be alternated in a radial fashion, thereby averaging the temperature of the heat exchanger fluid across the channels 232. In accordance with yet another embodiment, the input conduit 910 and the output conduit 920 are substantially in the same plane.

As mentioned above, the heat exchanger fluid is pumped into the heat exchanger 222 to remove heat from the substrate 110. Depending upon the substrate process temperature and the amount of heat flowing from the substrate 110 to the cathode pedestal 105, the temperature of the heat exchanger fluid may be below the freezing point of water, such as from about −20 degrees Celsius to about −10 degrees Celsius. If water is used as the heat exchanger fluid, anti-freeze chemicals, such as ethylene glycol or salts, may be added to the water. Non-water based fluids (such as, the fluorinated Galden HT-110, HT-135, and HT-200) may also be used as the heat exchanger fluid.

By using the various embodiments of the heat exchanger 222 described above, the substrate 110 may be cooled in a uniform manner and the temperature difference between the substrate 110 and the heat exchanger 222 may be kept at a minimum, e.g., less than about 5 degrees Celsius at 2000 Watts thermal load for a 300 mm substrate. Although the heat exchanger 222 has been described with reference to cooling the substrate 110, the heat exchanger 222 may also be used to heat the cathode pedestal 105.

While the foregoing is directed to embodiments of the present invention, other and further embodiments of the invention may be devised without departing from the basic scope thereof, and the scope thereof is determined by the claims that follow.

What is claimed is:

1. A plasma etch reactor, comprising:
a chamber;
a pedestal disposed within the chamber;
a gas distribution plate disposed within the chamber overlying the pedestal;
a ring surrounding the pedestal, wherein the ring defines a raised portion; and
an upper electrically conductive mesh layer and a lower electrically conductive mesh layer disposed within the pedestal, wherein the upper electrically conductive mesh layer is disposed substantially above the lower electrically conductive mesh layer and is substantially the same size as a substrate configured to be disposed on the pedestal, and wherein the lower electrically conductive mesh layer is substantially annular in shape and is disposed around a periphery of the upper electrically conductive mesh layer and below the raised portion of the ring.

2. The reactor of claim 1, wherein the raised portion is about 1.5 mm to about 3 mm taller than the surface of the substrate.

3. The reactor of claim 1, wherein the upper electrically conductive mesh layer, the lower electrically conductive mesh layer and the raised portion are configured to cause the electric field lines proximate a periphery of the substrate to be substantially perpendicular to the substrate.

4. The reactor of claim 1, wherein the lower electrically conductive mesh layer is disposed proximate a periphery of the pedestal.

5. The reactor of claim 1, wherein the pedestal is a cathode pedestal.

6. The reactor of claim 1, further comprising:
an insulation layer disposed on the pedestal; and
a plurality of gas flow openings disposed through the insulation layer, wherein at least one gas flow opening comprises a porous plug disposed therein, and
wherein the porous plug is configured to provide an indirect pathway for gases to flow toward an upper surface of the insulation layer.

7. The reactor of claim 6, wherein the porous plug is made from a dielectric material.

8. The reactor of claim 6, wherein the porous plug is made from a material selected from a group consisting of ceramic compositions, engineering thermoplastics, thermosetting resins, filled, engineering thermoplastics, filled thermosetting resins, and combinations thereof.

9. The reactor of claim 6, wherein the porous plug is made from alumina having a porosity ranging from about 10% in volume to about 60% in volume.

10. The reactor of claim 6, wherein the indirect pathway avoids a straight line of sight configuration.

11. The reactor of claim 1, further comprising at least one lift pin opening disposed through the pedestal, wherein the at least one lift pin opening comprises a lift pin disposed therein configured to lift a portion of a substrate off an upper surface of the pedestal, and wherein the at least one lift pin opening has a pressure that is substantially less than a pressure inside the chamber during a process.

12. The reactor of claim 1, further comprising a heat exchanger disposed inside the pedestal, wherein the heat exchanger comprises a plurality of channels, wherein each channel defines a plurality of protrusions disposed therein, wherein the protrusions are configured to cause turbulence to a heat exchanger fluid contained inside the channels.

13. The reactor of claim 1, further comprising an RF bias generator electrically coupled to the upper electrically conductive mesh layer and the lower electrically conductive mesh layer.

14. The reactor of claim 1, further comprising an insulation layer disposed on the pedestal, wherein the insulation layer has a thickness from about 25 mm to about 30 mm.

15. The reactor of claim 13, wherein a plasma generated inside the chamber has a conductance from about 0.001+j0.01 to about 0.004+j0.02.

16. The reactor of claim 13, wherein the electrically conductive mesh layers are electrically coupled to the RF bias generator through at least one of an RF conductor and an RF bias impedance match element.

17. The reactor of claim 13, further comprising:
a bias power feed point at a surface of the substrate;
an RF conductor connected between the RF bias generator and the bias power feed point; and
a dielectric sleeve surrounding a portion of the RF conductor, wherein the sleeve has an axial length along the RF conductor, a dielectric constant and an axial location along the RF conductor such that the sleeve provides a reactance that substantially enhances plasma ion density uniformity over the surface of the substrate.

18. The reactor of claim 17, further comprising a VHF power source for supplying power to the gas distribution plate, wherein the feed point has an impedance at a VHF power frequency, and wherein the reactance of the sleeve brings the impedance of the feed point at the VHF power frequency to a value closer to an impedance of about zero.

19. A plasma etch reactor, comprising:
a chamber;
a pedestal disposed within the chamber;
a gas distribution plate disposed within the chamber overlying the pedestal; and
at least one lift pin opening disposed through the pedestal, wherein the at least one lift pin opening comprises a lift pin disposed therein configured to lift a portion of a substrate off an upper surface of the pedestal, and wherein the at least one lift pin opening has a pressure that is substantially less than a pressure inside the chamber during a process.

20. The reactor of claim 19, wherein the at least one lift pin opening is pumped with vacuum.

21. A plasma etch reactor, comprising:
a chamber;
a pedestal disposed within the chamber;
a gas distribution plate disposed within the chamber overlying the pedestal; and
a heat exchanger disposed inside the pedestal, wherein the heat exchanger comprises a plurality of channels, wherein each channel defines a plurality of protrusions disposed therein, wherein the protrusions are configured to cause turbulence to a heat exchanger fluid contained inside the channels.

22. The reactor of claim 21, wherein each protrusion is one of a fin, a chevron and a bump.

23. The reactor of claim 21, wherein the channels are configured such that the heat exchanger fluid contained in adjacent channels travels in opposite directions.

24. An apparatus for supporting a semiconductor substrate processing reactor, comprising:
a pedestal;
a ring surrounding the pedestal, wherein the ring defines a raised portion; and
an upper electrically conductive mesh layer and a lower electrically conductive mesh layer disposed within the pedestal, wherein the upper electrically conductive mesh layer is disposed substantially above the lower electrically conductive mesh layer and is substantially the same size as a substrate configured to be disposed on the pedestal, and wherein the lower electrically conductive mesh layer is substantially annular in shape and is disposed around a periphery of the upper electrically conductive mesh layer and below the raised portion of the ring.

25. The apparatus of claim 24, wherein the lower electrically conductive mesh layer is disposed proximate a periphery of the pedestal.

26. The apparatus of claim 24, wherein the pedestal is a cathode pedestal.

27. The apparatus of claim 24, further comprising:
an insulation layer disposed on the pedestal; and
a plurality of gas flow openings disposed through the insulation layer, wherein at least one gas flow opening comprises a porous plug disposed therein, and wherein the porous plug is configured to provide an indirect pathway for gases to flow toward an upper surface of the insulation layer.

28. The apparatus of claim 27, wherein the porous plug is made from a dielectric material.

29. The apparatus of claim 27, wherein the porous plug is made from a material selected from a group consisting of ceramic compositions, engineering thermoplastics, thermosetting resins, filled engineering thermoplastics, filled thermosetting resins, and combinations thereof.

30. The apparatus of claim 27, wherein the porous plug is made from alumina having a porosity ranging from about 10% in volume to about 60% in volume.

31. The apparatus of claim 27, wherein the indirect pathway avoids a straight line of sight configuration.

32. The apparatus of claim 24, further comprising at least one lift pin opening disposed through the pedestal, wherein the at least one lift pin opening comprises a lift pin disposed therein configured to lift a portion of a substrate off an upper surface of the pedestal, and wherein the at least one lift pin opening has a pressure that is substantially less than a pressure during operation of a chamber in which the pedestal is contained.

33. The apparatus of claim 32, wherein the at least one lift pin opening is pumped with vacuum.

34. The apparatus of claim 24, further comprising a heat exchanger disposed inside the pedestal, wherein the heat exchanger comprises a plurality of channels, wherein each channel defines a plurality of protrusions disposed therein, wherein the protrusions are configured to cause turbulence to a heat exchanger fluid contained inside the channels.

35. The apparatus of claim 34, wherein each protrusion is one of a fin, a chevron and a bump.

36. The apparatus of claim 34, wherein the channels are configured such that the heat exchanger fluid contained in adjacent channels travels in opposite directions.

37. The apparatus of claim 24, further comprising an insulation layer disposed on the pedestal, wherein the insulation layer has a thickness from about 25 mm to about 30 mm.

38. An apparatus for supporting a semiconductor substrate processing reactor, comprising:
a pedestal; and
at least one lift pin opening disposed through the pedestal, wherein the at least one lift pin opening comprises a lift pin disposed therein, and wherein the at least one lift pin opening has a pressure that is substantially less than a pressure during operation of a chamber in which the pedestal is contained.

39. The apparatus of claim 38, wherein the at least one lift pin opening is pumped with vacuum.

40. An apparatus for supporting a semiconductor substrate processing reactor, comprising:
a pedestal; and
a heat exchanger disposed inside the pedestal, wherein the heat exchanger comprises a plurality of channels, wherein each channel defines a plurality of protrusions disposed therein, wherein the protrusions are configured to cause turbulence to a heat exchanger fluid contained inside the channels.

41. The apparatus of claim 40, wherein each protrusion is one of a fin, a chevron and a bump.

42. The apparatus of claim 40, wherein the channels are configured such that the heat exchanger fluid contained in adjacent channels travels in opposite directions.
